(19) United States
(12) Patent Application Publication
(10) Pub. No.: US 2008/0151117 A1
(43) Pub. Date: Jun. 26, 2008

(54) HORIZONTAL SYNCHRONOUS CIRCUIT, DISPLAY DEVICE, AND CLOCK ADJUSTING METHOD

(75) Inventor: Kenichi Horikoshi, Kumagaya-shi (JP)

Correspondence Address: PILLSBURY WINTHROP SHAW PITTMAN, LLP, P.O. BOX 10500, MCLEAN, VA, 22102, US

(73) Assignee: KABUSHIKI KAISHA TOSHIBA, Tokyo (JP)

(21) Appl. No.: 11/774,173

(22) Filed: Jul. 6, 2007

(30) Foreign Application Priority Data
Dec. 26, 2006 (JP) P2006-350663

(51) Int. Cl. H03L 7/00

(52) U.S. Cl. 348/537

(57) ABSTRACT

This horizontal synchronous circuit is a horizontal synchronous circuit generating a first horizontal synchronizing signal synchronous with a second horizontal synchronizing signal included in a video signal, and includes: a PLL oscillator generating a pixel clock signal; a phase comparator outputting a difference signal of the first horizontal synchronizing signal and the second horizontal synchronizing signal; a filter filtering the difference signal with a predetermined time constant to output, to the PLL oscillator, the resultant as a correction signal for the PLL oscillator; a counter divider counting the pixel clock signal generated by the PLL oscillator and outputting a pulse signal every predetermined count number to generate the first horizontal synchronizing signal; and a count controller temporarily changing the time constant of the filter based on an instruction from a user and controlling the count number of the counter divider while the time constant is changed.

### CROSS-REFERENCE TO RELATED APPLICATIONS

This application is based upon and claims the benefit of priority from the prior Japanese Patent Application No. 2006-350663, filed on Dec. 26, 2006; the entire contents of which are incorporated herein by reference.

### BACKGROUND

1. Field of the Invention

The present invention relates to a horizontal synchronous circuit, a display device, and a clock adjusting method.

2. Description of the Related Art

Generally, a display device using an analog video signal A/D-converts the analog video signal and takes in sample pixels in a horizontal direction according to a sampling clock signal, thereby displaying an image. However, since the analog video signal includes a distortion component and a phase difference arisen from external noise and the like, it is not sometimes possible to take in all the horizontal pixels if the sampling clock signal is fixed.

For example, the total number of horizontal pixels (the total number of dot clocks) of XGA is 1344 dots, but the occurrence of the signal distortion and phase difference disturbs an analog waveform, which is a factor to cause an error in the A/D conversion. Therefore, in order to take in all the horizontal pixels of the XGA, the number of samples is adjusted to 1345 or 1343 by controlling sampling clock of the A/D conversion.

For stable horizontal synchronization of video, an A/D converter thus processing an analog video signal generates a synchronizing signal with a horizontal synchronous frequency by counting the number of sampling clocks. Then, a PLL circuit is structured by using the generated synchronizing signal with the horizontal synchronous frequency and a horizontal synchronizing signal of an input video signal, thereby stabilizing the horizontal synchronous frequency. If the aforesaid sampling clock control is performed in the A/D converter as structured above, the horizontal frequency in the A/D converter changes at an instant when the number of samples changes, so that a phenomenon occurs that a display image falls out of horizontal synchronization, resulting in the disturbance of the image.

As a technique to stabilize the horizontal synchronization, there has been proposed a horizontal synchronous circuit as disclosed in, for example, JP-A 2000-184230 (KOKAI). However, in the horizontal synchronous circuit according to this proposal, since the horizontal synchronization is controlled based on lack of the horizontal synchronization, a sufficient effect has not been obtained against the aforesaid disturbance of the image arisen from the sampling clock control of the A/D converter.

### SUMMARY

As described above, conventional horizontal synchronous circuits, display devices, clock adjusting methods have a problem that a sufficient effect cannot be obtained against the disturbance of an image ascribable to the sampling clock control of an A/D converter processing an analog video signal.

The present invention was made to solve such a problem, and an object thereof is to provide a horizontal synchronous circuit, a display device, a clock adjusting method realizing sampling clock control with reduced image disturbance.

To attain the above object, a horizontal synchronous circuit according to one aspect of the present invention is a horizontal synchronous circuit generating a first horizontal synchronizing signal synchronous with a second horizontal synchronizing signal included in a video signal, the circuit including: a PLL oscillator generating a pixel clock signal; a phase comparator outputting a difference signal of the first horizontal synchronizing signal and the second horizontal synchronizing signal; a filter filtering the difference signal with a predetermined time constant to output, to the PLL oscillator, the resultant as a correction signal for the PLL oscillator; a counter divider counting the pixel clock signal generated by the PLL oscillator and outputting a pulse signal every predetermined count number to generate the first horizontal synchronizing signal; and a count controller temporarily changing the time constant of the filter based on an instruction from a user and controlling the count number of the counter divider while the time constant is changed.

A display device according to another aspect of the present invention is a display device displaying an image of an inputted video signal, the device including: a horizontal synchronous circuit which generates a first horizontal synchronizing signal synchronous with a second horizontal synchronizing signal included in the video signal and includes: a PLL oscillator generating a pixel clock signal; a phase comparator outputting a difference signal of the first horizontal synchronizing signal and the second horizontal synchronizing signal; a filter filtering the difference signal with a predetermined time constant to output, to the PLL oscillator, the resultant as a correction signal for the PLL oscillator; a counter divider counting the pixel clock signal generated by the PLL oscillator and outputting a pulse signal every predetermined count number to generate the first horizontal synchronizing signal; and a count controller temporarily changing the time constant of the filter based on an instruction from a user and controlling the count number of the counter divider while the time constant is changed; a display unit displaying an image; and a driver controlling the display unit based on the first horizontal synchronizing signal outputted by the horizontal synchronous circuit.

A clock adjusting method according to still another aspect of the present invention is a clock adjusting method of a horizontal synchronous circuit which includes: an oscillator generating a pixel clock signal; a counter divider counting the pixel clock signal generated by the oscillator, in a predetermined sampling unit to generated a horizontal synchronizing signal; a comparator outputting a difference signal of a horizontal synchronizing signal included in a video signal and the horizontal synchronizing signal generated by the counter divider; and a filter filtering the difference signal with a predetermined time constant to generate a correction signal for an oscillation frequency of the oscillator, the method comprising: changing the time constant of the filter; changing the sampling unit after changing the time constant of the filter; and returning the time constant of the filter to an original value after changing the sampling unit.

### BRIEF DESCRIPTION OF THE DRAWINGS

FIG. 1 is a block diagram showing the configuration of a horizontal synchronous circuit according to a first embodiment of the present invention.

FIG. 2 is a flowchart showing the operation of the horizontal synchronous circuit according to the first embodiment.

FIG. 3 is a block diagram showing the configuration of a horizontal synchronous circuit according to a second embodiment of the present invention.

FIG. 4 is a flowchart showing the operation of the horizontal synchronous circuit according to the second embodiment.

FIG. 5 is a block diagram showing the configuration of a display device according to a third embodiment of the present invention.

### DETAILED DESCRIPTION

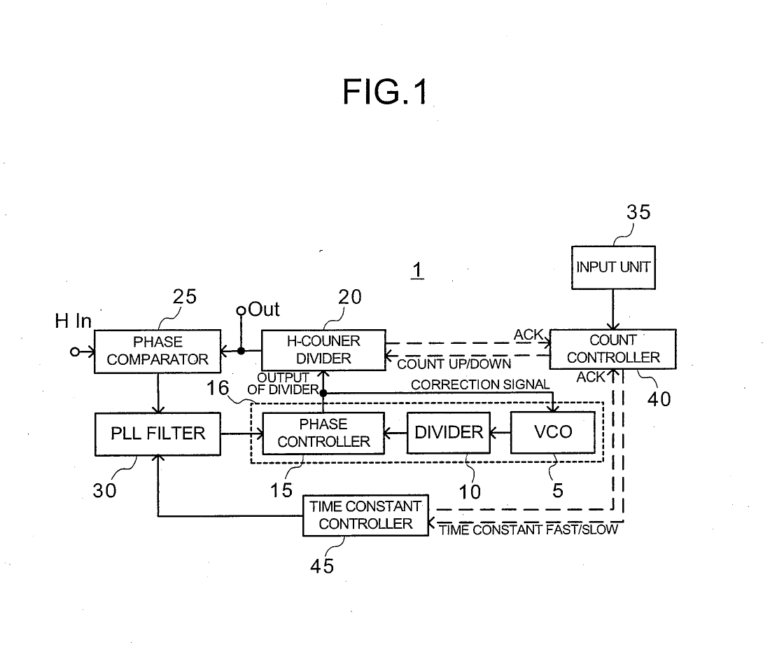

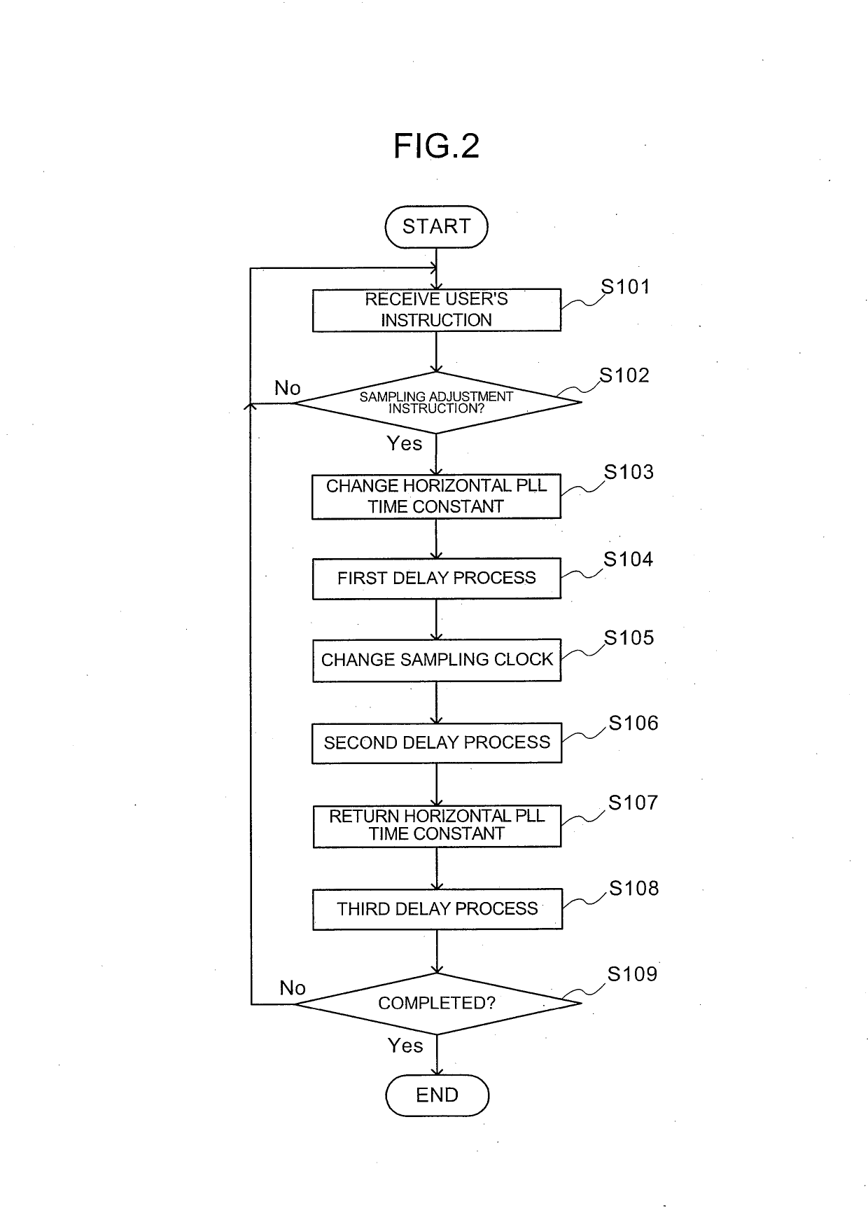

Hereinafter, one embodiment of the present invention will be described in detail with reference to the drawings. FIG. 1 is a block diagram showing the configuration of a horizontal synchronous circuit according to a first embodiment of the present invention, and FIG. 2 is a flowchart showing the operation of the horizontal synchronous circuit according to this embodiment. The horizontal synchronous circuit 1 of this embodiment realizes the acquisition of all horizontal pixels by controlling sampling clock. As shown in FIG. 1, the horizontal synchronous circuit 1 includes a PLL oscillator 16 in which a voltage-controlled oscillator (VCO) 5, a divider 10, and a phase controller 15 are provided, an H-counter divider 20, a phase comparator 25, a PLL filter 30, an input unit 35, a count controller 40, and a time constant controller 45.

The VCO 5 is an oscillator generating a reference signal serving as a reference of a horizontal synchronizing signal. The VCO 5 generates the signal with a frequency corresponding to a predetermined multiple of pixel clock (dot clock). The divider 10 divides the frequency of the reference signal generated by the VCO 5 to output a pixel clock signal. The phase controller 15 compares a later-described signal sent from the PLL filter 30 and a frequency-divided signal outputted from the divider 10 to generate a difference signal and feeds back the difference signal to the VCO 5. That is, the VCO 5, the divider 10, and the phase controller 15 constitute the PLL oscillator 16. The PLL oscillator 16 supplies the output of the divider 10 (the pixel clock signal) to the H-counter divider 20.

The H-counter divider 20 is a divider counting inputted clocks to output a pulse every time a predetermined count number is reached. The H-counter divider 20 counts the pixel clock signal sent from the PLL oscillator 16 to output a pulse every predetermined count number. Here, the predetermined count number is decided based on the total number of horizontal pixels. For example, taking the aforesaid XGA as an example, the H-counter divider 20 counts the inputted pixel clock signal to output one pulse to the phase comparator 25 every time the count number reaches 1344 as the predetermined counter number. That is, the H-counter divider 20 has a function of dividing the pixel clock to a horizontal synchronous frequency.

The H-counter divider 20 also has a function of changing the predetermined count number based on an external instruction. That is, when receiving a count up/down signal from an external part, the H-counter divider 20 increments or decrements the predetermined counter number by one. After changing the predetermined count number, the H-counter divider 20 returns an Ack signal to a transmitting end of the count up/down signal.

The phase comparator 25 compares a horizontal synchronizing signal of a video signal inputted via a HIn terminal and the frequency-divided signal sent from the H-counter divider 20 (the horizontal synchronizing signal generated by the H-counter divider 20) to output a difference therebetween. That is, the phase comparator 25 compares the horizontal synchronizing signal generated by the PLL oscillator 16 and the H-counter divider 20 with the horizontal synchronizing signal obtained from the video signal to output a difference therebetween as an error signal. The phase comparator 25 sends the error signal to the PLL filter 30.

The PLL filter 30 is a loop filter having a predetermined time constant. The PLL filter 30 has a function of filtering the error signal sent from the phase comparator 25, with the predetermined time constant to output the resultant as a correction signal. The time constant of the PLL filter 30 is changeable from an external part. Specifically, when a time constant fast/slow signal is received from the external part, the predetermined time constant of the PLL filter 30 is shortened or lengthened.

The input unit 35 is an input interface receiving a sampling clock control instruction (count number increment/decrement instruction) from a user. The count controller 40 controls the time constant of the PLL filter 30 and the increment/decrement of the predetermined counter number of the H-count divider 20, based on the count number increment/decrement instruction received by the input unit 35. Concretely, based on the count number increment/decrement instruction, the count controller 40 shortens the time constant of the PLL filter 30 (makes it faster) to improve sensitivity of the PLL filter 30, then controls the increment/decrement of the count number of the H-counter divider 20, and thereafter returns the time constant of the PLL filter 30 to an original predetermined value. Consequently, the convergence of the horizontal synchronous frequency accompanying a change in the number of sampling clocks becomes faster, which can reduce the influence on a display screen to a minimum.

The time constant controller 45 receives an instruction for controlling the time constant of the PLL filter 30 from the count controller 40 to control the time constant of the PLL filter 30. The time constant controller 45 returns an Ack signal to the count controller 40 after changing the time constant of the PLL filter 30.

Next, the operation of the horizontal synchronous circuit 1 of this embodiment will be described with reference to FIG. 2. In this horizontal synchronous circuit 1, the VCO 5 generates the reference signal to supply it to the divider 10. The divider 10 divides the frequency of the reference signal generated by the VCO 5 to supply the resultant to one input of the phase controller 15. Here, the horizontal synchronizing signal included in the video signal is supplied to the HIn terminal. In a case where the horizontal synchronizing signal included in the video signal and the horizontal synchronizing signal outputted from the H-counter divider 20 are synchronous with each other, that is, in a case where the horizontal synchronous frequency of the horizontal synchronous circuit 1 is convergent, the phase comparator 25 does not output the error signal, and therefore, the correction signal for the PLL oscillator 16 is not outputted from the PLL filter 30. Therefore, the correction signal for the PLL oscillator 16 is not supplied to the other input of the phase controller 15.

In such a case, the frequency control according to the feedback signal sent from the phase controller 15 to the VCO 5 is not performed since the horizontal synchronous frequency is convergent. The PLL oscillator 16 supplies the signal generated by the divider 10 as it is to the H-counter divider 20.

The H-counter divider 20 receives from the PLL oscillator 16 the signal frequency-divided by the divider 10 (=the pixel clock signal) and counts its pulses. When the predetermined count number is reached, the H-counter divider 20 supplies only one pulse signal to the phase comparator 25 and resumes the counting. As a result, the H-counter divider 20 generates the horizontal synchronizing signal to supply it to the phase comparator 25 and to output it to an Out terminal.

Here, when the horizontal synchronizing signal of the video signal inputted via the HIn terminal and the horizontal synchronizing signal outputted from the H-counter divider 20 become asynchronous, the phase comparator 25 outputs the error signal indicating a difference value therebetween to the PLL filter 30. The PLL filter 30 filters the error signal with the predetermined time constant and outputs the resultant as the correction signal for the PLL oscillator 16 to the other input of the phase controller 15.

As a result, the output signal of the phase controller 15 changes, so that the signal fed back to the VCO 5 also changes and an oscillation frequency of the VCO 5 changes. The change of the oscillation frequency of the VCO 5 causes a change in the frequency of the signal supplied to the H-counter divider 20 and also a change in the horizontal synchronous frequency of the horizontal synchronizing signal supplied to the phase comparator 25. Finally, the error signal of the phase comparator 25 becomes zero, resulting in the convergence of these changes, so that the horizontal synchronous frequency is stabilized.

Here, when the input unit 35 receives an instruction input from a user (Step 101. Hereinafter, such steps are written as “S101” and the like.), the input unit 35 determines whether or not the instruction input is a sampling adjustment instruction (S102).

When it is found as a result of the determination that the instruction from the user is the sampling adjustment instruction, that is, a sample number increment/decrement instruction (Yes at S102), the count controller 40 sends the time constant controller 45 an instruction signal for shortening the time constant of the PLL filter 30 (for making it faster). When receiving the instruction signal, the time constant controller 45 performs the control to shorten the time constant of the PLL filter 30 (S103). Then, the time constant controller 45 returns the Ack signal to the count controller 40 at a timing when the error signal outputted from the phase comparator 25 becomes zero (at a timing when the PLL loop becomes convergent) (S104). That is, the time constant controller 45 changes the time constant of the PLL filter 30, and after waiting for the PLL loop to be stabilized, it returns the Ack signal. This delay time is on the order of about several m-seconds.

When receiving the Ack signal from the time constant controller 45, the count controller 40 sends the H-counter divider 20 a count number instruction signal based on the instruction of the user. When receiving the instruction signal, the H-counter divider 20 changes the count number according to the contents of the instruction from the user (S105). For example, in a case of the aforesaid XGA, 1344 as a standard value is increased to 1345 or decreased to 1343. The H-counter divider 20 returns the Ack signal to the count controller 40 at the timing when the error signal outputted from the phase comparator 25 becomes zero (at the timing when the PLL loop becomes convergent) (S106). This delay time is also on the order of about several m-seconds.

When receiving the Ack signal from the H-counter divider 20, the count controller 40 sends the time constant controller 45 an instruction signal for returning the time constant of the PLL filter 30 to the standard value. When receiving the instruction signal, the time constant controller 45 performs the control to return the time constant of the PLL filter 30 to the standard value (S107). The time constant controller 45 returns the Ack signal to the count controller 40 at a timing when the error signal outputted from the phase comparator 25 becomes zero (at a timing when the PLL loop becomes convergent) (S108). This delay time is also on the order of several m-seconds.

When the instruction sent from the input unit 35 has been completely processed or there is no more instruction (Yes at S109), the count controller 40 finishes the sampling number increment/decrement process. When the instruction has not been completely processed or there still exists an instruction, the count controller 40 receives the instruction input (S101).

As described above, according to the horizontal synchronous circuit of this embodiment, when the count number of the divider generating the horizontal synchronizing signal is changed, the control is performed so that the time constant of the PLL filter is shortened (its sensitivity is improved), which can reduce the disturbance of the display image to a minimum. Further, according to the horizontal synchronous circuit of this embodiment, since the delay process is inserted between the processes, it is possible to stabilize the horizontal synchronizing signal without disturbing the convergence operation of the PLL. Incidentally, the delay before the Ack signal is returned may be omitted.

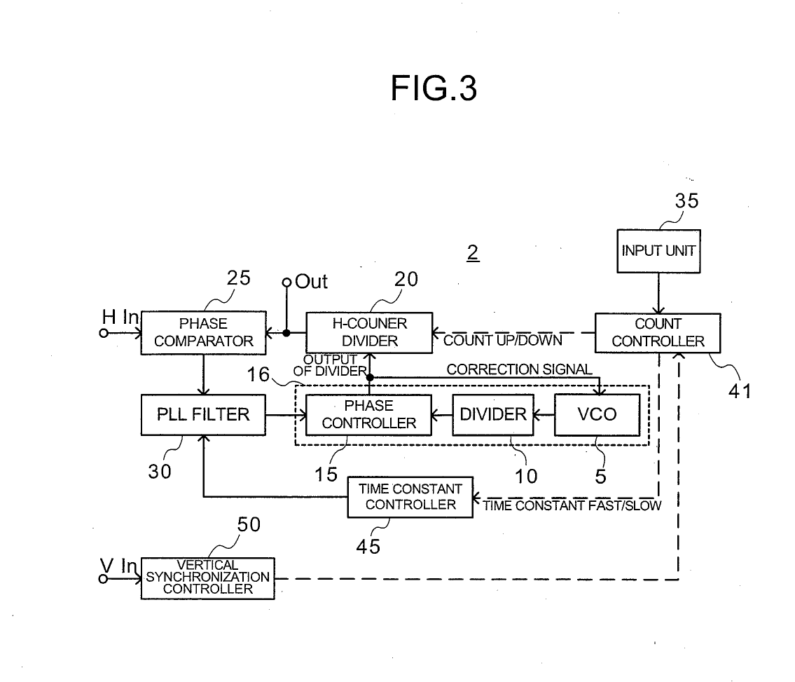

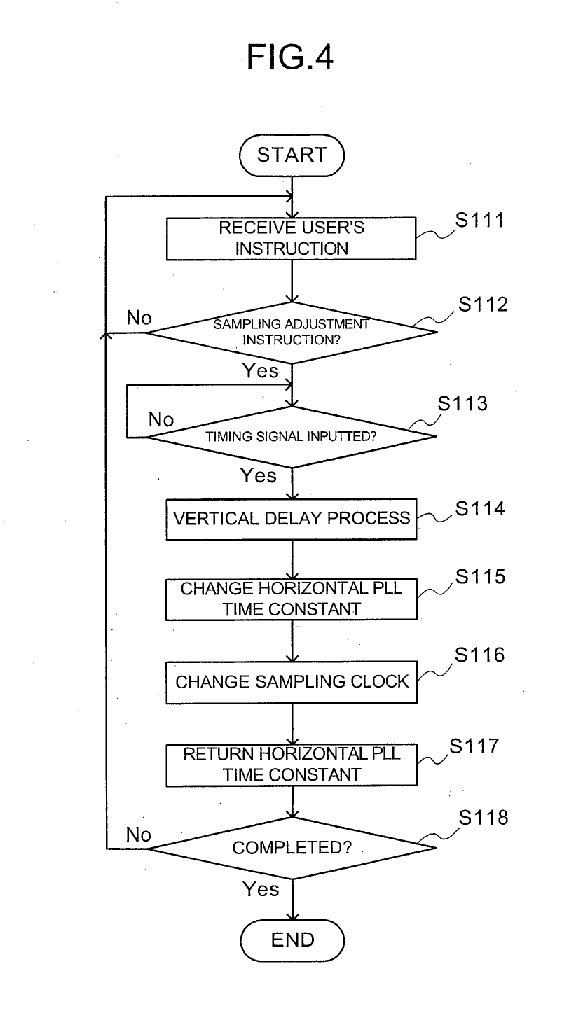

Next, another embodiment of the present invention will be described in detail. FIG. 3 is a block diagram showing the configuration of a horizontal synchronous circuit according to a second embodiment of the present invention, and FIG. 4 is a flowchart showing the operation of the horizontal synchronous circuit according to this embodiment. As shown in FIG. 3, the horizontal synchronous circuit 2 of this embodiment further includes a vertical synchronization controller 50 in addition to the configuration of the horizontal synchronous circuit 1 according to the first embodiment shown in FIG. 1. Hence, elements common to the first embodiment are denoted by the common reference numerals and symbols, and repeated description thereof will be omitted.

The vertical synchronization controller 50 is a pulse generator having a VIn terminal to which a vertical synchronizing signal of a video signal is inputted and giving a count controller 41 a pulse signal (timing signal) indicating a timing of a vertical retrace period. The vertical synchronization controller 50 has a function of giving the timing signal indicating a timing for the count controller 41 to perform a count number increment/decrement process.

The count controller 41 has the same function as that of the count controller 40 of the first embodiment, but is different therefrom in that the count controller 41 operates according to pulses sent from the vertical synchronization controller 50 and operates differently in controlling the time constant controller 45 and the H-counter divider 20.

Hereinafter, the operation of the horizontal synchronous circuit 2 shown in FIG. 3 will be described with reference to FIG. 4. A convergence behavior of a horizontal synchronous frequency in the horizontal synchronous circuit 2 is the same as the convergence behavior in the first embodiment and therefore description thereof will be omitted.

The vertical synchronizing signal of the video signal is inputted to the VIn terminal of the vertical synchronization controller 50, and the vertical synchronization controller 50 sends the timing signal synchronous with the vertical retrace period to the count controller 41. Here, when the input unit 35 receives an instruction input from a user (S111), the input unit 35 determines whether or not this input is a sampling adjustment instruction (S112).

In a case where it is found as a result of the determination that the instruction from the user is a sampling adjustment instruction, that is, a sample number increment/decrement instruction (Yes at S112), the count controller 41 waits until it receives the timing signal from the vertical synchronization controller 50 (S113/No at S113). When receiving the timing signal from the vertical synchronization controller 50 (Yes at S113), the count controller 41 sends the time constant controller 45 an instruction signal for shortening the time constant of the PLL filter 30 (for making it faster). Here, a timing to send the instruction signal needs to coincide with the next vertical retrace period, and therefore, a vertical delay operation (vertical delay process) is inserted (S114). When receiving the instruction signal, the time constant controller 45 performs the control to shorten the time constant of the PLL filter 30 (S115). In the horizontal synchronous circuit of the first embodiment, the delay operation is performed in order to wait for the convergence of the PLL, but in the horizontal synchronous circuit of the second embodiment, since the process is performed within the vertical retrace period, no delay operation is needed.

Subsequently, the count controller 41 sends the H-counter divider 20 a count number instruction signal based on the instruction of the user. When receiving the instruction signal, the H-counter divider 20 changes the count number according to the contents of the instruction from the user (S116). For example, in a case of the aforesaid XGA, 1344 as a standard value is increased to 1345 or decreased to 1343. In this operation, the delay operation to wait for the convergence of the PLL is also unnecessary.

Further, the count controller 40 sends the time constant controller 45 an instruction signal for returning the time constant of the PLL filter 30 to the standard value. When receiving the instruction signal, the time constant controller 45 performs the control to return the time constant of the PLL filter 30 to the standard value (S117).

When the instruction sent from the input unit 35 has been completely processed or there is no more instruction (Yes at S118), the count controller 40 finishes the sample number increment/decrement process. When the instruction has not been completely processed or there is still an instruction, the count controller 40 receives the instruction input (S111).

As described above, according to the horizontal synchronous circuit of this embodiment, since the sample number increment/decrement process is performed within the vertical retrace period, the disturbance of the display image can be further reduced. Incidentally, in the description of the horizontal synchronous circuit of the second embodiment, neither the time constant controller 50 nor the H-counter divider 20 sends the Ack signal to the count controller 41, but this is not restrictive. The Ack signal may be transmitted after each operation providing that the operation can be finished within the vertical retrace period.

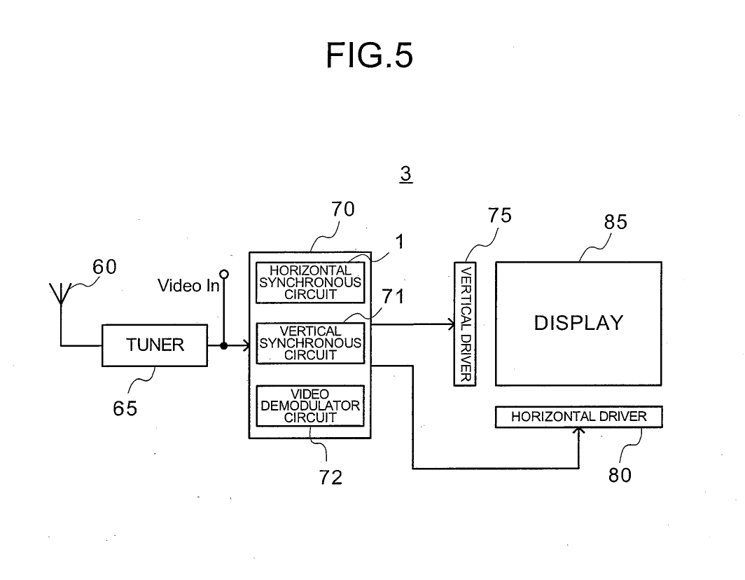

Next, a display device according to a third embodiment of the present invention will be described in detail with reference to FIG. 5. As shown in FIG. 5, this display device 3 includes an antenna 60, a tuner 65, a video signal processor 70, a vertical driver 75, a horizontal driver 80, and a display 85, and also functions as a television apparatus. Note that FIG. 5 mainly shows the configuration involved in the scanning of the display.

The antenna 60 receives television broadcast waves. The tuner 65 selects a desired broadcast wave from radio waves received by the antenna 60. The video signal processor 70 demodulates the broadcast wave selected by the tuner 65 to a horizontal synchronizing signal, a vertical synchronizing signal, a video signal, and a sound signal. The vertical driver 75 and the horizontal driver 80 scan the display 85 in a vertical direction and a horizontal direction respectively for the video signal.

The video signal processor 70 includes the horizontal synchronous circuit 1 according to the first embodiment, a vertical synchronous circuit 71, and a video demodulator circuit 72. Incidentally, the video signal processor 70 may include the horizontal synchronous circuit 2 of the second embodiment in place of the horizontal synchronous circuit 1 according to the first embodiment. Further, instead of the antenna 60 and the tuner 65, a video signal input unit VideoIn may be provided to directly receive the video signal.

According to the display device of this embodiment, since the horizontal synchronous circuit according to the first or second embodiment is provided, the disturbance of a display image accompanying a change in the count number of the divider generating the horizontal synchronous signal is reduced to a minimum, which enables sampling clock control with reduced image disturbance.

It should be noted that the present invention is not limited exactly to the above-described embodiments, but when being implemented, the invention may be embodied by modifying the constituent elements without departing from the spirit of the present invention. Further, various inventions can be formed by appropriate combination of the plural constituent elements disclosed in the above-described embodiments. For example, some constituent elements out of all the constituent elements shown in the embodiments may be deleted. Further, constituent elements in different embodiments may be appropriately combined.

What is claimed is:

1. A horizontal synchronous circuit generating a first horizontal synchronizing signal synchronous with a second horizontal synchronizing signal included in a video signal, the circuit comprising:
a PLL oscillator generating a pixel clock signal;
a phase comparator outputting a difference signal of the first horizontal synchronizing signal and the second horizontal synchronizing signal;
a filter filtering the difference signal with a predetermined time constant to output, to said PL oscillator, the resultant as a correction signal for said PLL oscillator;
a counter divider counting the pixel clock signal generated by said PLL oscillator and outputting a pulse signal every predetermined count number to generate the first horizontal synchronizing signal; and
a count controller temporarily changing the time constant of said filter based on an instruction from a user and controlling the count number of said count divider while the time constant is changed.

2. The horizontal synchronous circuit according to claim 1,
wherein said PLL oscillator comprises:
a voltage-controlled oscillator oscillating a reference signal;
a divider frequency-dividing the reference signal to generate the pixel clock signal; and
a phase controller comparing the pixel clock signal generated by said divider and the correction signal for said PLL oscillator to generate a correction signal for said voltage-controlled oscillator.

3. The horizontal synchronous circuit according to claim 1, wherein the predetermined count number is a total number of horizontal pixels of the video signal.

4. The horizontal synchronous circuit according to claim 1, wherein said count controller changes the count number after changing the time constant to a shorter value, and returns the time constant to an original value after the change of the count number is completed.

5. The horizontal synchronous circuit according to claim 1, further comprising a vertical synchronization controller generating a timing signal indicating a timing of a vertical retrace period of the video signal, based on a vertical synchronizing signal included in the video signal,
wherein said count controller changes the time constant and controls the count number during the vertical retrace period, based on the timing signal generated by said vertical synchronization controller.

6. A display device displaying an image of an inputted video signal, comprising:
a horizontal synchronous circuit which generates a first horizontal synchronizing signal synchronous with a second horizontal synchronizing signal included in the video signal and comprises:
a PLL oscillator generating a pixel clock signal;
a phase comparator outputting a difference signal of the first horizontal synchronizing signal and the second horizontal synchronizing signal;
a filter filtering the difference signal with a predetermined time constant to output, to said PLL oscillator, the resultant as a correction signal for said PLL oscillator;
a counter divider counting the pixel clock signal generated by said PLL oscillator and outputting a pulse signal every predetermined count number to generate the first horizontal synchronizing signal; and
a count controller temporarily changing the time constant of said filter based on an instruction from a user and controlling the count number of said counter divider while the time constant is changed;
a display unit displaying the image; and
a driver controlling said display unit based on the first horizontal synchronizing signal outputted by said horizontal synchronous circuit.

7. The display device according to claim 6, wherein said PLL oscillator comprises:
a voltage-controlled oscillator oscillating a reference signal;
a divider frequency-dividing the reference signal to generate the pixel clock signal; and
a phase controller comparing the pixel clock signal generated by said divider and the correction signal for said PLL oscillator to generate a correction signal for said voltage-controlled oscillator.

8. The display device according to claim 6, wherein the predetermined count number is a total number of horizontal pixels of the video signal.

9. The display device according to claim 6, wherein said count controller changes the count number after changing the time constant to a shorter value, and returns the time constant to an original value after the change of the count number is completed.

10. The display device according to claim 6, further comprising a vertical synchronization controller generating a timing signal indicating a timing of a vertical retrace period of the video signal, based on a vertical synchronizing signal included in the video signal,
wherein said count controller changes the time constant and controls the count number during the vertical retrace period, based on the timing signal generated by said vertical synchronization controller.

11. A clock adjusting method of a horizontal synchronous circuit which comprises: an oscillator generating a pixel clock signal; a counter divider counting the pixel clock signal generated by the oscillator, in a predetermined sampling unit to generated a horizontal synchronizing signal; a comparator outputting a difference signal of a horizontal synchronizing signal included in a video signal and the horizontal synchronizing signal generated by the counter divider; and a filter filtering the difference signal with a predetermined time constant to generate a correction signal for an oscillation frequency of the oscillator, the method comprising:
changing the time constant of the filter;
changing the sampling unit after changing the time constant of the filter; and
returning the time constant of the filter to an original value after changing the sampling unit.
